(19) United States
(12) Patent Application Publication
(10) Pub. No.: US 2024/0186105 A1
(43) Pub. Date: Jun. 6, 2024

(54) DEVICES AND SYSTEMS FOR SPATIAL SUBTRACTION OF ELECTRON BACKSCATTER DIFFRACTION PATTERNS

(71) Applicant: Katholieke Universiteit Leuven, Leuven (BE)

(72) Inventor: Etienne Brodu, Leuven (BE)

(21) Appl. No.: 18/526,286

(22) Filed: Dec. 1, 2023

Related U.S. Application Data
(60) Provisional application No. 63/385,823, filed on Dec. 2, 2022.

(51) Int. Cl. H01J 37/22; H01J 37/295

(52) U.S. Cl. CPC H01J 37/222; H01J 37/295; H01J 2237/153

(57) ABSTRACT

A set of methods of processing a set of Kikuchi diffraction patterns acquired for a series of incident positions of an electron beam on a sample material are described. One such method involves the steps of identifying a first pattern in the set containing a matrix signal and suspected of additionally containing a secondary phase signal; identifying a second pattern close to the first pattern which contains a matrix signal without containing a secondary phase signal; modifying the contrast and intensity of either the first pattern or the second pattern, the modification depending on a relative property of the first and second patterns, resulting in a modified first or second pattern; and obtaining a secondary phase signal pattern by either i) if the first pattern was modified, subtracting the original second pattern from the modified first pattern; or ii) if the second pattern was modified, subtracting the modified second pattern from the original first pattern.

### CROSS-REFERENCE TO RELATED APPLICATION

This application claims the benefit under 35 U.S.C. § 119(e) of U.S. Provisional Patent Application Ser. No. 63/385,823, filed Dec. 2, 2022, the disclosure of which is hereby incorporated herein in its entirety by this reference.

### TECHNICAL FIELD

The application relates to methods for processing Kikuchi diffraction patterns, more specifically methods for extracting a secondary phase signal from a pair of Kikuchi diffraction patterns.

### BACKGROUND

Electron microscopy is a widely used microscopy technique used in the study of crystalline materials, in which a beam of accelerated electrons is aimed at a sample and the behavior of the electron beam after interaction with the sample is analyzed to obtain information about the microstructure of the sample.

It is common in electron microscopy that the electron-matter interaction volume is of comparable size to the characteristic length scale of the microstructure analyzed. In such a situation, the measured diffraction patterns tend to consist of mixtures of overlapped signals emitted by different crystals. There is therefore a need for first separating the overlapped signals and then generating meaningful information from the separated signals, ideally spatially resolved.

Orientation mapping by transmission electron microscopy (TEM) allows indexing multiple contributions in overlapped spot diffraction patterns as a result of the presence along the depth of a thin foil of several crystals on top of each other. As the main application, the separation of signals in overlapped precession electron diffraction (PED) patterns allows the generation of 3D orientation maps of microstructures at the nanoscale. Likewise, conical-scanning dark-field imaging also allows reconstruction of microstructures in 3D. In both cases, such signal separation from different crystals is possible because spots are discrete points in patterns and tend to not interfere with one another.

In the case of Kikuchi diffraction, like in electron backscatter diffraction (EBSD) or transmission Kikuchi diffraction (TKD), the diffraction signal takes the form of extended features, bands, and lines. The overlap of several diffraction signals from several crystals results in complex mixtures of patterns and separation of the contributions is challenging. For this reason, a limitation in EBSD analysis has long been that only a single, predominant signal can be indexed for each pattern of an orientation map. This means that a large number of fine-scale microstructural features is commonly missing from the orientation map.

One option to avoid such signal overlap and allow analysis of finer microstructures would be to reduce the size of the electron-matter interaction volume. This could be achieved with low-keV EBSD, typically at 5 keV. However, new challenges emerge in this regime. First, because the diffraction wave absorption length strongly decreases with decreasing electron energy, sample preparation for such low-keV EBSD experiments is challenging. Due to the increase of the Kikuchi band width with decreasing energy, the detection of the Kikuchi band is also less reliable, in particular, if the detection relies on the Hough transform.

In parallel, there has been a recent renewed interest in the treatment of overlapped patterns. Recently, Shi et al. (2021) and Lenthe et al. (2020) showed the ability of the Pattern Matching technique (Ram & De Graef, 2018; Singh et al., 2018; Winkelmann et al., 2018, 2020) to separate and index up to three overlapped signals. However, this progress did not yet translate into the resolution of finer microstructures, because in the first case the information generated was not spatially resolved, and in the second case, the signal separation was aimed at analyzing grain boundaries (see also Fullwood et al., 2021).

Therefore, there is a need for accurate signal separation methods for Kikuchi diffraction patterns, which are acquired using standard EBSD or TKD hardware. There is also a need for signal separation methods, which can be performed on patterns obtained using standard sample preparation and pattern acquisition processes. There is also a need for signal separation methods for extracting phases with a size below 100 nm while using standard incident electron beam energy.

There is also a need for signal separation methods, which can adapt to a set of patterns such that if a first signal separation method is not suitable, a second signal separation method is triggered instead.

### BRIEF SUMMARY

According to a first aspect of the disclosure, there is provided a method of processing a set of Kikuchi diffraction patterns acquired for a series of incident positions of an electron beam on a sample material, the method comprising the steps of:
identifying a first pattern (or target pattern) in the set containing a matrix signal and suspected of additionally containing a secondary phase signal;
identifying a second pattern (or template pattern) close to the first pattern, which contains a matrix signal without containing a secondary phase signal;
modifying the contrast and intensity of either the first pattern or the second pattern, the modification depending on a relative property of the first and second patterns, resulting in a modified first or second pattern; and
obtaining a secondary phase signal pattern by either i) if the first pattern was modified, subtracting the original second pattern from the modified first pattern; or ii) if the second pattern was modified, subtracting the modified second pattern from the original first pattern.

According to a second aspect of the disclosure there is provided a method of processing a set of Kikuchi diffraction patterns acquired for a series of incident positions of an electron beam on a sample material, the method comprising the steps of:
identifying a first pattern in the set containing a matrix signal and suspected of additionally containing a secondary phase signal;
identifying a second pattern close to the first pattern, which contains a matrix signal only;
providing a metric-contrast correlation measure, being a measure of a correlation between on the one hand a relative property of any pair of patterns in the set, one containing a matrix signal only and the other containing a matrix signal and a secondary phase signal, and on the other hand a correction factor required to cancel the matrix signal from the pattern containing the secondary phase signal;
if the correlation measure is less than a predetermined threshold value, carrying out a blind signal separation method on the first and second patterns;
if the correlation measure is greater than the predetermined threshold value, modifying the contrast and intensity of either the first pattern or the second pattern, the modification depending on a relative property of the first and second patterns, resulting in a modified first or second pattern, and subtracting the modified/original second pattern from the original/modified first pattern.

The relative property may be the distance between the respective incident positions of the electron beam for the first and the second patterns. The relative property may be the difference between the pattern quality index of the first pattern and of the second pattern.

The method may comprise the step of, before subtracting the second pattern from the first pattern, applying a misorientation correction to the first and second (modified) patterns based on an FFT phase correlation. According to a third aspect of the disclosure there is provided a method of processing a set of EBSD (or TKD) patterns acquired for a series of incident positions of an electron beam on a sample material, the method comprising the steps of:
identifying a first pattern in the set containing a matrix signal and suspected of additionally containing a secondary phase signal;
identifying a second pattern close to the first pattern, which contains a matrix signal only;
carrying out a blind signal separation method on the first and second patterns.

The method may comprise a noise filtering step before carrying out the blind signal separation.

The blind signal separation method may provide third and fourth patterns as output, the method comprising computing a correlation coefficient of each of the third and the fourth patterns with the second pattern and discarding the pattern that has the highest correlation with the second pattern.

Identifying the first pattern may comprise identifying a pattern with a pattern quality index, which is less than a predetermined threshold value.

Identifying the second pattern may comprise identifying a pattern with a pattern quality index, which is more than a predetermined threshold value.

It is an advantage of embodiments of the disclosure that phases whose size is well below 100 nm can be mapped at standard EBSD incident energies.

### BRIEF DESCRIPTION OF THE DRAWINGS

Certain embodiments of the disclosure will now be described, by way of example, with reference to the accompanying drawings, in which:

FIG. 1 is a flowchart of a method according to embodiments of the disclosure;

FIG. 2 shows template patterns, target patterns, subtraction without correction, and subtraction after correction using a method according to embodiments of the disclosure;

FIG. 3 shows EBSD patterns in various stages of processing: Part (a) of FIG. 3 is the as-captured pattern; Part (b) of FIG. 3 shows the average of several patterns captured at a surface scratch; Part (c) of FIG. 3 shows the result of the subtraction of Part b of FIG. 3 from Part a of FIG. 3; Part (d) of FIG. 3 shows the low frequency component of part (c) of Part c of FIG. 3; Part (e) of FIG. 3 shows part (c) of FIG. 3 after division by part (d) of FIG. 3; and Part (f) of FIG. 3 shows the contrast enhancement of Part e of FIG. 3.

FIG. 4 illustrates various steps in a method according to embodiments of the disclosure: Part (a) of FIG. 4 shows a scanning electron image; Part (b) of FIG. 4 shows the image of Part (a) of FIG. 4 with tilt correction; Part (c) of FIG. 4 illustrates setting of an IQ threshold; Part (d) of FIG. 4 illustrates pairing of a target pattern and a nearby template pattern; Part (e) of FIG. 4 shows three template patterns; Part (f) of FIG. 4 shows three target patterns corresponding to the template patterns of Part (e) of FIG. 4; Part (g) of FIG. 4 shows indexing of the target patterns, where the minority phase is not detectable; Part (h) of FIG. 4 shows the result of contrast correction on the target patterns followed by subtraction of the corresponding template patterns according to embodiments of the disclosure; and Part (i) of FIG. 4 shows indexing of the patterns in 4h in which the minority phase is now detectable;

FIG. 5 is an illustration of the output from the pattern postprocessing routine applied to a nanolamellar pearlitic steel. A comparison with the EBSD map generated from the original unprocessed patterns on the same area and identification of the cementite-ferrite orientation relationship is shown;

FIG. 6 shows an illustration of the output from the pattern postprocessing routine applied to a nanolamellar pearlitic steel on a large area. Comparison with the EBSD map generated from the original unprocessed patterns is also shown;

FIG. 7 shows a comparison of the angular resolutions achieved by two indexing methods on the same postprocessed patterns. Unlike Hough indexing, Pattern Matching allows resolution of the intragranular misorientations in cementite;

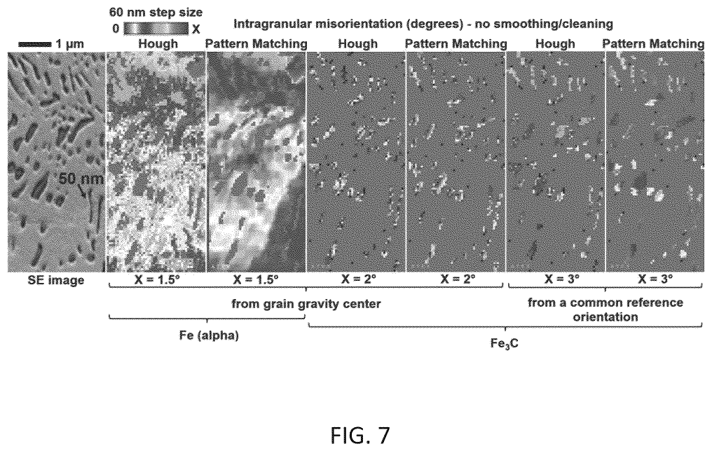

FIG. 8 is a flowchart of a method according to embodiments of the disclosure.

The drawings are only schematic and are non-limiting. In the drawings, the size of some of the elements may be exaggerated and not drawn on scale for illustrative purposes.

Any reference signs in the claims shall not be construed as limiting the scope.

In the different drawings, the same reference signs refer to the same or analogous elements.

### DETAILED DESCRIPTION

Methods described herein according to embodiments of the disclosure are concerned with processing diffraction patterns obtained by electron microscopy measurements performed on samples containing a matrix phase having a generally continuous character and a secondary phase, which is dispersed within the matrix phase. Microstructural features like nanoscale minority phases inside larger matrix grains emit weak signals overwhelmed by the signal generated by the surrounding matrix, meaning that such minority phases are difficult or impossible to detect.

The disclosure allows such minority phases to be extracted from Kikuchi diffraction patterns, that is, electron beam diffraction patterns that include Kikuchi lines. Kikuchi lines are lines produced by electrons that are Bragg scattered by inelastic scattering sites within the sample, and occur in pairs. Such diffraction patterns can be produced by electron backscatter diffraction and by transmission Kikuchi diffraction. Generally, a set of diffraction patterns is acquired for a series of incident positions of an electron beam on the sample material.

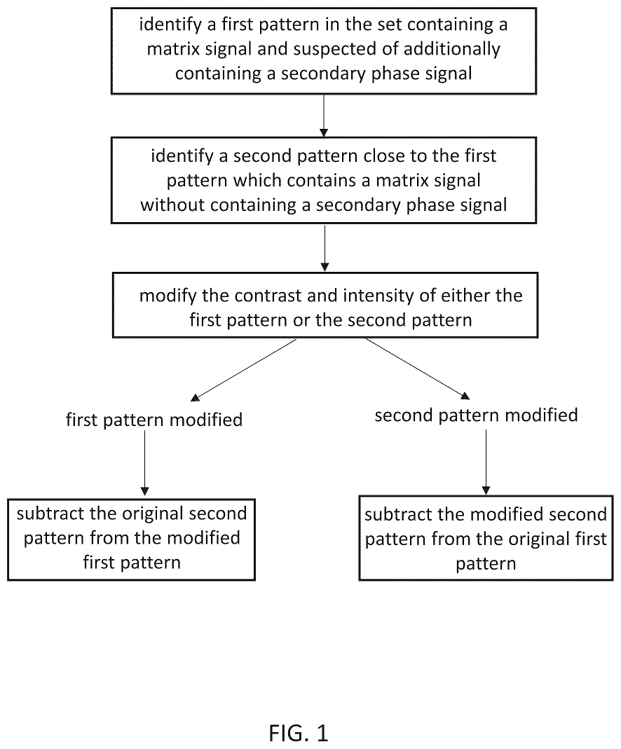

Referring to FIG. 1, a method according to embodiments of the disclosure comprises the following steps.

### Step S1

A first pattern, or target pattern, is identified in the set of Kikuchi diffraction patterns, the first pattern being a pattern that contains a matrix signal and is suspected of containing a secondary phase signal. The matrix signals referred to herein are signals resulting from the large matrix grains forming the bulk structure of the sample. The secondary phase signals referred to herein are phase signals resulting from nanoscale phases inside larger matrix grains in the sample. Kikuchi diffraction patterns at standard electron beam energy levels, generally around 10-20 keV, tend to be dominated by the matrix phase, with secondary phases being effectively invisible.

The identification of the first pattern can be done, for example, by considering the pattern quality index (also referred to as IQ, “image quality”) of a given pattern. This is a parameter calculated based on the intensity of a selection of the most intense Kikuchi bands in a given pattern and generated by most commercial EBSD acquisition software. Pattern quality can be thought of as a measurement of how sharp or fuzzy a diffraction pattern is. A description of a calculation of IQ can be found in “EBSD Pattern Quality and its Use in Evaluating Sample Surface Condition,” S. D. Sitzman et al., Microsc. Microanal. 16 (Suppl 2), 2010. In short, a Hough transform is performed on the diffraction pattern image. The IQ value for the pattern is calculated by averaging the height of a selected number of the highest peaks (most intense diffraction bands) of the Hough transform. Patterns whose strongest bands are higher in intensity than those of other patterns, in general, result in higher pattern quality values. The IQ value is sensitive to pattern degradation from any source, including by signal overlap. The patterns of interest, or target patterns, are patterns with an IQ lower than the matrix material. The target patterns can thus be discriminated by making use of an IQ threshold: patterns having an IQ value less than a predetermined threshold can be identified as target patterns containing a matrix signal and suspected of containing a secondary phase signal.

The predetermined threshold can be set for a given map, for example, by treating the pattern quality distribution for the map as a bimodal distribution. The threshold can be set automatically as the bin with the lowest population between the two centroids of the bimodal distribution.

The predetermined threshold may alternatively be set manually, which can allow the final number of correctly indexed patterns of the minority phases to be maximized.

### Step S2

A second pattern, or template pattern, in the set of patterns is identified, the second pattern being a pattern that contains a matrix signal and does not contain a secondary phase signal. The second pattern may be identified as being a template pattern by use of the threshold value, i.e., being a pattern, which has an IQ value higher than the predetermined threshold value. The threshold value may be modified for step S2, for example, by slightly increasing the value.

The second pattern is a pattern that is close to the first pattern, that is, adjacent or almost adjacent to the first pattern. The second pattern is generally the nearest matrix-only pattern to the first pattern. Here, “close” or “near” is meant in the sense of the relative position of the incident electron beam.

### Step S3

In step S3, the contrast and intensity of either the first pattern or the second pattern is modified. The modification depends on a relative property of the first and second patterns. This results in a modified first pattern, if the contrast and intensity of the first pattern is modified, or a modified second pattern, if the contrast and intensity of the second pattern is modified.

The aim of step S3 is to match the contrasts of the matrix signals comprised in the first and the second patterns as accurately as possible, so that the matrix signals can be cancelled by subtraction in order to reveal the minority phase signal. In order to achieve this cancellation, the contrast of the first pattern needs to be increased before subtraction (or the contrast of the second pattern needs to be decreased before subtraction), because pattern overlap causes patterns containing a matrix phase signal and a secondary phase signal to have a slightly lower contrast than patterns containing a matrix phase signal only.

The contrast can be modified by multiplication of a pattern by a contract-enhancement multiplication factor. The contract-enhancement multiplication factor may be determined, for example, as follows. A user selects several pairs of first and second patterns and manually adjusts the contrast of either the first or the second pattern (the pattern to be adjusted being always the first pattern for all pairs of patterns, or always the second pattern for all pairs of patterns) such that the matrix signal is cancelled. Each pair of patterns then has an associated contract-enhancement multiplication factor. Then the relative IQ, i.e., the difference in the IQ between the IQ of the first and the IQ of the second pattern, is determined for each pair. This gives a set of relative IQ values and contract-enhancement multiplication factors. A function can be fitted to this dataset such that for a given relative IQ value for a first and a second pattern as identified in steps S1 and S2, an appropriate contract-enhancement multiplication factor can be determined.

In some embodiments, instead of the contrast, the intensity can be modified. In some embodiments, the relative IQ value is replaced by the spatial distance between the two patterns, being determined as the distance between the respective incident positions of the electron beam for the first and the second patterns. Other relative values of the first and second patterns are possible within the scope of the disclosure.

The choice to use IQ value or distance can be made depending on properties of the EBSD maps. For maps with minority phases with a relatively large size distribution, the contrast enhancement factor tends to vary with distance, such that the larger the distance between paired target (first) and template (second) patterns, the larger the contrast enhancement factor applied to the target pattern and vice versa. The reason is that the contrast difference of matrix signals between paired target and template patterns tends to show a stronger correlation with distance than IQ difference when minority phases vary in size within a map. On the other hand, with a close to constant target-template pattern distance, the contrast difference is better correlated with the IQ difference for minority phases of narrow size distribution (the larger the gap between the IQ of the target pattern and the IQ threshold, the larger the contrast enhancement factor applied to the target pattern).

Optionally, two further contrast enhancement factors may be used, which are fixed for a given map but do not vary from one target pattern to another. These focus on the signal distribution within patterns. It was observed that target patterns tend to have a different signal distribution than template patterns, with a slightly lower relative contrast in their lower half. For this reason, the two further contrast enhancement factors can be used to adjust the contrast enhancement from top to bottom in target patterns. These two factors are set independently and are directly applied to the first and last row of pixels in target patterns, while in-between pixels are multiplied instead by a linearly deduced factor function of row position. In some embodiments this additional contrast modification is not necessary. Too much increase of the contrast of target patterns should be avoided. If the contrast of a target pattern ends up higher than the contrast of the corresponding template pattern, subtraction of the two patterns will leave bright Kikuchi bands associated with the matrix contribution. An insufficient contrast enhancement results in dark matrix Kikuchi bands, not detected by Hough-detection during pattern reindexing, which is a lot more desirable.

Optionally, in some embodiments, at the end of Step S3 a routine based on FFT phase correlation may be implemented in order to correct for possible slight misorientation between the matrix contributions in the target and template patterns. With this routine, the template pattern is translated in order to match with the target pattern. Since the misorientation is small (because the distance between target and template is also small) neglecting the gnomonic projection and position of the pattern center may in some embodiments give satisfactory results. For the same reason, the in-plane rotation may also be neglected.

In some embodiments, the relative pattern rotation may be corrected. The correction can be done on one or the other of the two patterns of a pair, not necessarily on the pattern above the threshold.

### Step S4

In step S4, a secondary phase signal pattern is obtained by either i) if the first pattern contrast or intensity was modified in step S3 based on the relative property, subtracting the original second pattern from the modified first pattern; or ii) if the second pattern contrast or intensity was modified in step S3 based on the relative property, subtracting the modified second pattern from the original first pattern. This results in a pattern showing only the weak secondary signal of the nanoscale minority phase.

Finally, an optional normalization of the intensity of the resulting pattern can be performed.

As an optional step, a new EBSD file can be generated that contains all the original patterns that are above the IQ threshold, plus the processed target patterns. This new file can then be reindexed like any other EBSD file (done with OIM8-EDAX in the example shown herein). It is worth noting that the Hough-based band detection with appropriate parameter settings allows to correctly index patterns with a highly varying signal over noise ratio within a single map, which makes it well suited to the present methodology. However, other band detection/indexing methods may be used within the scope of the disclosure.

### Example Implementation

An example implementation of embodiments of the disclosure is now described, without wishing to limit the scope of the disclosure to the specifics of this particular implementation.

Nanolamellar pearlite is a material that has long been out of reach for EBSD for two reasons. First, because the electron-matter interaction volume produced by EBSD extends well beyond cementite precipitates and lamellae of that size, patterns seemingly contain only a ferrite signal. Second, even if the lamellae are wide enough to generate patterns with cementite as the predominant signal, the low symmetry of cementite generates complex patterns that quickly become too messy for indexing if a secondary ferrite signal is also present. Nanolamellar pearlite is just one example of a range of materials that can be analyzed using EBSD methods according to embodiments of the disclosure.

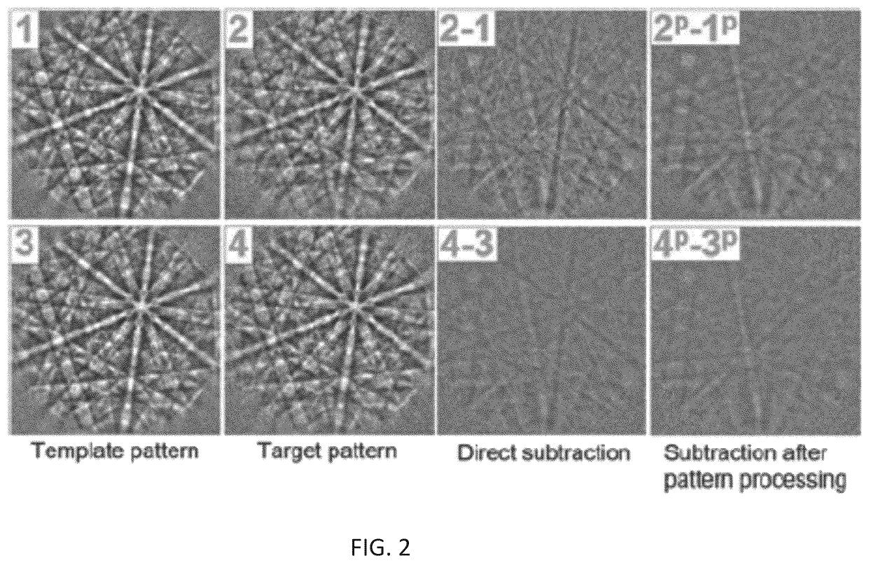

Cementite is left undetected by conventional indexing routines because patterns show seemingly only ferrite signals for any beam position on the surface. Vet, a weak secondary signal associated with cementite and invisible to the naked eye is also present and overlaps the dominant ferrite signal when the beam position is near a lamella (these overlapped patterns are referred to as target patterns). The only visible difference between patterns containing a secondary signal (target patterns) and patterns containing only information from ferrite (template patterns) is that target patterns have a slightly lower contrast because of the overlapping of two different crystals by the interaction volume. Because of this contrast difference, a direct close-neighbor pattern subtraction of target patterns by template patterns does not allow retrieval of the secondary signal. This can be seen from FIG. 2, which shows template patterns (FIG. 2a), target patterns (FIG. 2b), subtraction without correction (FIG. 2c), and subtraction after correction using a method according to embodiments of the disclosure (FIG. 2d).

The method is demonstrated on C75 steel with a chemical composition as follows (weight %): C 0.76, Mn 0.65, Si 0.21, P<0.04, S 0.016. The resulting microstructure is fully pearlitic with about 12 vol % cementite. Heat treatment was performed as follows: austenitization at 825° ° C. for 2 h, followed by salt bath at 680° C. for 15 min, and finally water quenching to room temperature, giving a mean interlamellar spacing of 350 nm.

Sample preparation is often critical for the success of an EBSD analysis. In multiphase materials like pearlite, the different phases should be as much as possible at the same height relative to the surface. Surface preparation for pearlite consisted of grinding with 1,200-4,000 grit papers, followed by manual polishing with 3-μm and 1-μm water-based diamond solutions on a napped cloth, and a final polish for 2 min with an oxide polishing suspension (OPS) solution. As a result of the higher etching speed by OPS of cementite, cementite is slightly lower than ferrite relative to the surface by typically 20 nm. In order to level the two phases relative to the surface, the sample was finally etched in Nital 0.1% for 2 s (the selective etching of Nital is opposite to that of OPS).

The diffraction patterns were recorded with a CCD-based EBSD camera (EDAX Hikari Super) in an FEI Nova NanoSEM 450 Scanning Electron Microscope. The acquisition parameters were selected to achieve the highest possible pattern quality. An energy of 15 keV was chosen in order to limit the size of the interaction volume while still having a high enough beam intensity (the intensity tends to strongly decrease with decreasing energy; lower-keV energies tend to generate lower quality diffraction patterns). Medium to large apertures were selected in order to reach a suitable trade-off between beam size and beam intensity.

An integration time of nearly 2 s per pattern, at 640×480 pixel resolution, was necessary in the used setup to achieve the required signal-to-noise ratio. A sub-100 nm step size was used in order to pick up the features of interest such as nanoscale minority phases. The combination of high integration time and small step-size results in significant surface contamination. For this reason, in situ plasma cleaning before each acquisition was performed. The tilt was set at 70°, and the working distance was set such that the projection of the pattern center on the EBSD detector was roughly at two thirds of the height from the bottom.

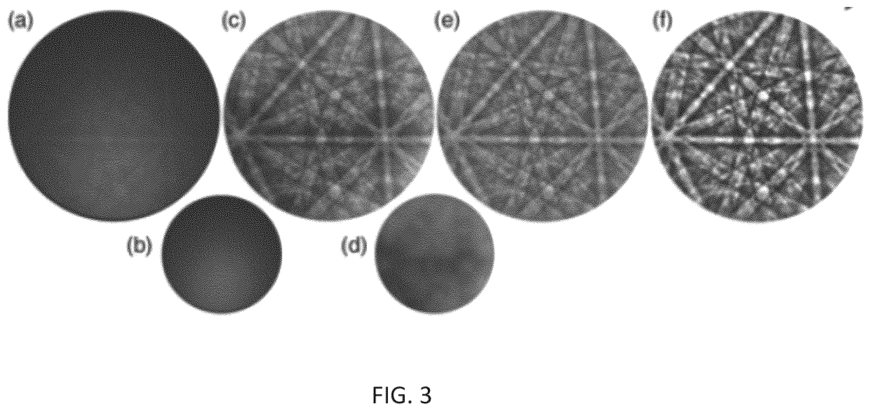

The diffraction patterns were saved as corrected as 8-bit images. The correction in this case consisted of a static background subtraction, a dynamic background division, and finally a contrast enhancement (FIG. 3). Part (a) of FIG. 3 shows the as-captured pattern. The patterns recorded and subsequently averaged for the static background subtraction were acquired on an area that was deliberately scratched and damaged to ensure that they contained no Kikuchi information (part (b) of FIG. 3, average of several patterns). Part c of FIG. 3 shows the result of subtracting the static background from part (a) of FIG. 3. The frequency threshold of the high-pass dynamic background division was set to low frequencies (part (d) of FIG. 3) in order to suppress as little as possible, the low-frequency component of the secondary Kikuchi signal of interest. Part e of FIG. 3 shows part (c) of FIG. 3 after division by part (d) FIG. 3.

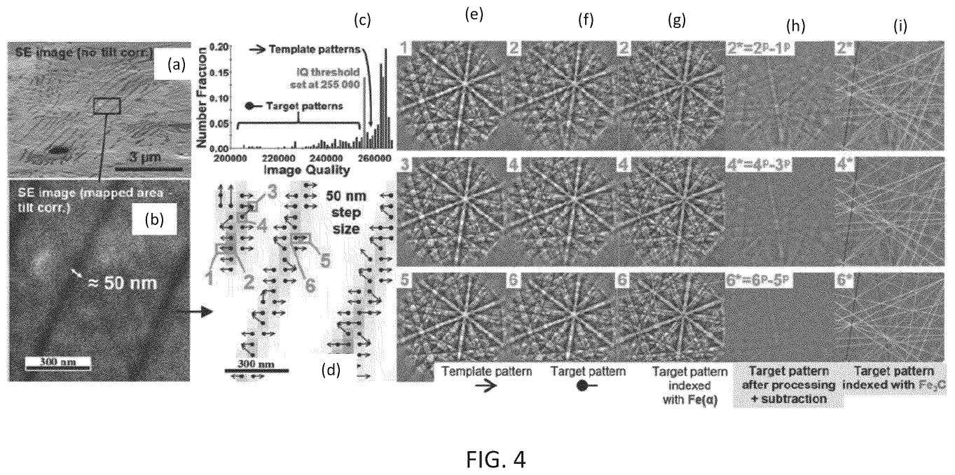

For identifying the target and template patterns, an IQ threshold was set based on the Hough transform (Part (c) of FIG. 4). Then, for each identified target pattern, a nearby template pattern was identified. The contrast adjustment was performed and followed by subtraction. Part (d) of FIG. 4 shows three template patterns, part (c) of FIG. 4 shows the associated identified target patterns, and Part (f) of FIG. 4 shows the result of Fe(a) indexing of the target patterns (without correction or subtraction). The processed patterns shown in Part (g) of FIG. 4 are the result of subtracting the template patterns from the target patterns, where the template patterns are first adjusted for orientation and the target patterns are first adjusted for contrast, as described hereinbefore. It is clear from the indexing of the processed patterns shown in Part (h) of FIG. 4 that the minority phase is now visible and detectable.

Thus, by using a method according to embodiments of the disclosure, the secondary signal can be retrieved while using standard electron beam diffraction energies.

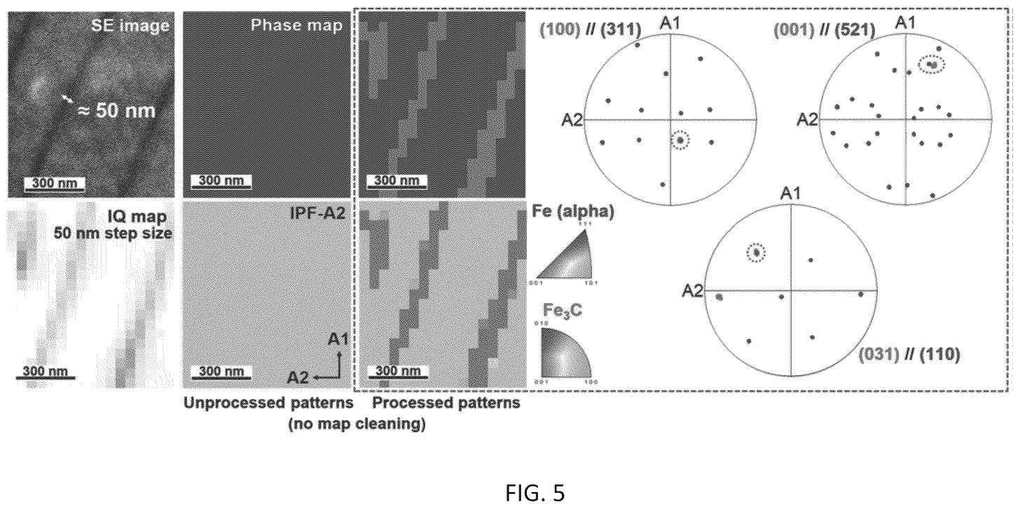

Further comparisons are shown in FIG. 5. It can be seen that without pattern processing, only a reduced area of cementite precipitates larger than 300 nm, corresponding to their center, is likely to appear in a map. In comparison, the present methodology allows indexing nearly all of the cementite in sub-100 nm lamellar pearlite. Also, it can be inferred from the observed cementite-ferrite orientation relationship (OR) in FIG. 5 that the orientation is most likely correct.

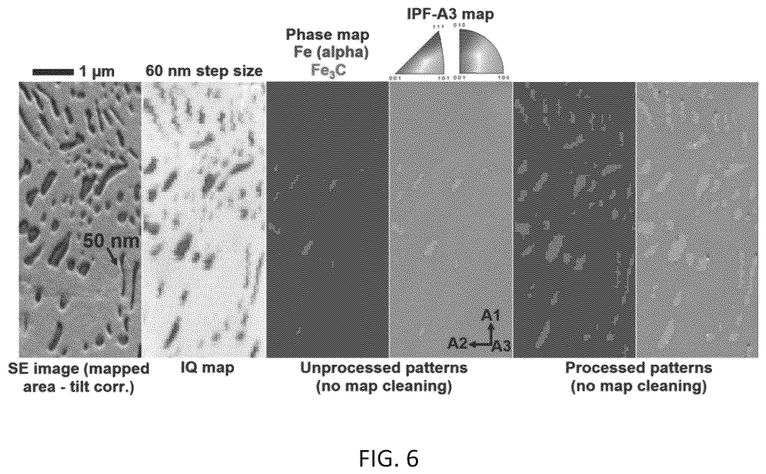

FIG. 6 shows that methods according to embodiments of the disclosure also allow the intragranular misorientation to be resolved, both in the ferritic matrix and in the cementite. However, the limited angular resolution of Hough indexing(0.5°) is borderline in its ability to resolve the very low misorientation of this specific microstructure. For this reason, a subsequent pattern matching-based orientation refinement method was used and compared to Hough indexing, which allows an order-of-magnitude improvement in angular sensitivity, see Winkelmann et al., “Improving EBSD precision by orientation refinement with full pattern matching,” J Microsc 277, 79-92.). FIG. 6 shows that fine details of ferrite and cementite substructures can be resolved by combining the close-neighbor pattern subtraction routine with pattern matching, which can be decisive in solving long-standing issues associated with the formation, transformation, and deformation mechanisms of pearlitic colonies.

In some embodiments, before carrying out step S1, a high-pass filter and/or kernel averaging of either the map of pattern quality index, the map of confidence index, the map of EDX signal (Energy-dispersive X-ray spectroscopy, usually conducted simultaneously with EBSD), or virtual FSD image may be carried out. Such metrics generally are generated by the commercial EBSD software used in acquiring and processing the patterns.

### Blind Signal Separation Method

In a further method according to embodiments of the disclosure, being a method of processing a set of Kikuchi diffraction patterns acquired for a series of incident positions of an electron beam on a sample material, the following steps are performed. First, a first (or target) pattern in the set is identified, containing a matrix signal and suspected of additionally containing a secondary phase signal. Second, a second (template) pattern close to the first pattern is identified, which contains a matrix signal only. The first and second steps are essentially the same as steps S1 and S2 outlined hereinbefore. Then, a blind signal separation (BSS) process is carried out on the first and second patterns. BSS advantageously allows for signal separation of minority phases without having to perform pattern subtraction.

BSS aims to separate a set of source signals from a set of mixed signals, with little or no information about the source signals or the mixing process. In the disclosure the source signals are the separate signals from the matrix phase and the minority phase, and the mixed signals are the EBSD patterns containing one or more of the source signals in unknown combinations with unknown relative weights. The objective of BSS is to recover the original component signals from the mixed signal.

Preferably at least two patterns are provided, since two source signals are desired to be extracted (the matrix signal and the minority phase signal). Each of the two patterns are made up of a mix of the two source signals, but the relative weights of the source signals is not the same from one pattern to the next. The relative weights are accumulated in a mixing matrix. The goal is to determine the unmixing matrix, i.e., the inverse of the mixing matrix, which allows the individual source signals to be extracted. The unmixing matrix can be determined using independent component analysis, where the unmixing matrix is searched by iteration, either to maximize the non-gaussianity of the estimated source signals, or by minimizing their mutual information.

### Combination Method

In a further method according to embodiments of the disclosure, a signal extraction route is chosen based on a correlation measure.

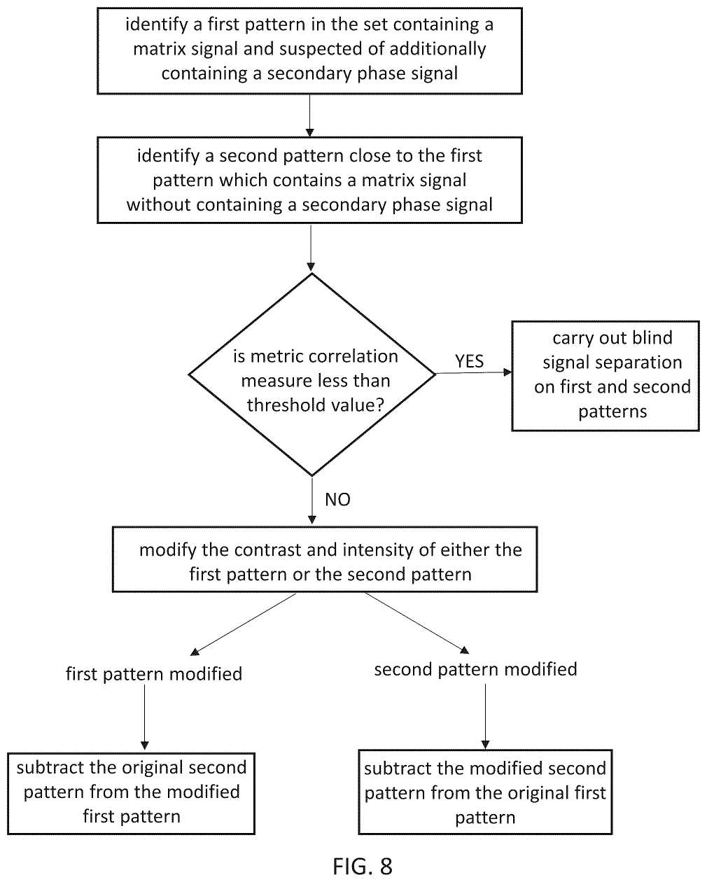

The method comprises the following steps (see also FIG. 8).

Steps S1 and S2 are the same as in the preceding methods described hereinbefore.

In step S3, a metric correlation measure is determined. As described hereinbefore, a correlation between the quality factor and a relative property of a target and a template signal may be determined. In some embodiments, this correlation may not be a good correlation. For example, two pairs of target/template patterns might have the same metric difference and yet require very different contrast factors. In such cases, the method described with respect to FIG. 1 may be unsuitable due to the difficulty in identifying an appropriate contrast/intensity correction factor due to poor correlation of the IQ and the relative property. Therefore, in the third method according to embodiments of the disclosure, the degree of correlation is assessed. If the correlation degree is below a predetermined threshold value, the subsequent signal separation method is chosen as blind signal separation (the second method), which does not rely on having a good correlation between IQ and relative property. If the correlation degree is above a predetermined threshold value, the correction and subtraction method is used (the first method). This allows an appropriate method to be chosen in each situation.

What is claimed is:

1. A method of processing a set of Kikuchi diffraction patterns acquired for a series of incident positions of an electron beam on a sample material, the method comprising the steps of:
identifying a first pattern in the set containing a matrix signal and suspected of additionally containing a secondary phase signal;
identifying a second pattern close to the first pattern, which contains a matrix signal without containing a secondary phase signal;
modifying the contrast and intensity of either the first pattern or the second pattern, the modification depending on a relative property of the first and second patterns, resulting in a modified first or second pattern; and
obtaining a secondary phase signal pattern by either i) if the first pattern was modified, subtracting the original second pattern from the modified first pattern; or ii) if the second pattern was modified, subtracting the modified second pattern from the original first pattern.

2. The method according to claim 1, wherein the relative property is a distance between the respective incident positions of the electron beam for the first and the second patterns.

3. The method according to claim 1, wherein the relative property is a difference between a pattern quality index of the first pattern and of the second pattern.

4. The method according to claim 1, comprising the step of, before subtracting the second pattern from the first pattern, applying a misorientation correction to the first and second (modified) patterns based on an FFT phase correlation.

5. The method according to claim 1, wherein identifying the first pattern comprises identifying a pattern with a pattern quality index, which is less than a predetermined threshold value.

6. The method according to claim 1, wherein identifying the second pattern comprises identifying a pattern with a pattern quality index, which is more than a predetermined threshold value.

7. A method of processing a set of Kikuchi diffraction patterns acquired for a series of incident positions of an electron beam on a sample material, the method comprising the steps of:
identifying a first pattern in the set containing a matrix signal and suspected of additionally containing a secondary phase signal;
identifying a second pattern close to the first pattern, which contains a matrix signal only;
providing a metric-contrast correlation measure, being a measure of a correlation between on the one hand a relative property of any pair of patterns in the set, one containing a matrix signal only and the other containing a matrix signal and a secondary phase signal, and on the other hand a correction factor required to cancel the matrix signal from the pattern containing the secondary phase signal;
if the correlation measure is less than a predetermined threshold value, carrying out a blind signal separation method on the first and second patterns; and
if the correlation measure is greater than the predetermined threshold value, modifying the contrast and intensity of either the first pattern or the second pattern, the modification depending on a relative property of the first and second patterns, resulting in a modified first or second pattern, and subtracting the modified/original second pattern from the original/modified first pattern.

8. The method according to claim 7, wherein the relative property is a distance between the respective incident positions of the electron beam for the first and the second patterns.

9. The method according to claim 7, wherein the relative property is a difference between a pattern quality index of the first pattern and of the second pattern.

10. The method according to claim 7, comprising the step of, before subtracting the second pattern from the first pattern, applying a misorientation correction to the first and second (modified) patterns based on an FFT phase correlation.

11. The method according to claim 7, wherein identifying the first pattern comprises identifying a pattern with a pattern quality index, which is less than a predetermined threshold value.

12. The method according to claim 7, wherein identifying the second pattern comprises identifying a pattern with a pattern quality index, which is more than a predetermined threshold value.

13. A method of processing a set of EBSD (or TKD) patterns acquired for a series of incident positions of an electron beam on a sample material, the method comprising the steps of:
identifying a first pattern in the set containing a matrix signal and suspected of additionally containing a secondary phase signal;
identifying a second pattern close to the first pattern, which contains a matrix signal only; and
carrying out a blind signal separation method on the first and second patterns.

14. The method according to claim 13, comprising a noise filtering step before carrying out the blind signal separation.

15. The method according to claim 13, wherein the blind signal separation method provides third and fourth patterns as output, the method comprising computing a correlation coefficient of each of the third and the fourth patterns with the second pattern and discarding the pattern, which has the highest correlation with the second pattern.

16. The method according to claim 13, wherein identifying the first pattern comprises identifying a pattern with a pattern quality index, which is less than a predetermined threshold value.

17. The method according to claim 13, wherein identifying the second pattern comprises identifying a pattern with a pattern quality index, which is more than a predetermined threshold value.
